(19) United States
(12) Patent Application Publication
(10) Pub. No.: US 2021/0026056 A1
(43) Pub. Date: Jan. 28, 2021

(54) LAMP USING SEMICONDUCTOR LIGHT-EMITTING DEVICES

(71) Applicant: LG ELECTRONICS INC., Seoul (KR)

(72) Inventors: Kwanwoo PARK, Seoul (KR); Kisuk WOO, Seoul (KR); Seokhoon KANG, Seoul (KR); Jeongin CHEON, Seoul (KR)

(73) Assignee: LG ELECTRONICS INC., Seoul (KR)

(21) Appl. No.: 16/968,099

(22) PCT Filed: Jul. 5, 2018
(86) PCT No.: PCT/KR2018/007640

§ 371 Date: Aug. 6, 2020

(30) Foreign Application Priority Data
Feb. 7, 2018 (KR) 10-2018-0015241

(51) Int. Cl. F21V 8/00

(52) U.S. Cl. CPC G02B 6/002; G02B 6/0055; G02B 6/0026; G02B 6/0031; G02B 6/0085; G02B 6/0068

(57) ABSTRACT

Discussed is a lamp or a lighting device including a substrate; a plurality of semiconductor light-emitting devices; a light guide layer provided with an incident light surface on which light emitted from the plurality of semiconductor light-emitting devices is incident and a light exit surface from which the light is emitted; a first reflective layer disposed on one surface of the light guide layer facing towards the light exit surface to reflect the light; and a second reflective layer disposed on another surface different from the one surface of the light guide layer on which the first reflective layer is disposed, wherein the first reflective layer is disposed on the same surface as the incident light surface, and wherein the second reflective layer is disposed obliquely to the incident light surface to allow light incident on the incident light surface to travel along the light guide layer

### BACKGROUND

### 1. Technical Field

The present disclosure relates to a lamp using semiconductor light-emitting devices, and more particularly, to a surface light source using semiconductor light-emitting devices.

### 2. Description of the Related Art

A surface light source using semiconductor light-emitting devices has an advantage of low power consumption and long lifespan compared to general lighting, and is used in various places and products such as flat panel lighting and backlight.

The surface light source using semiconductor light-emitting devices is largely divided into a direct type and an edge type, and in the case of the edge type, it has an advantage of generating a thin and uniform surface light source with a small number of light sources. In particular, in household appliances, for example, refrigerators, the need for thin lighting is increasing in order to increase internal capacity and insulation space. In order to implement various designs in interior lighting, the development of high-quality thin lighting is in progress.

A small semiconductor light-emitting device and a thin light guide plate are essential to construct a slim lighting device in an edge type. In recent years, with the development of semiconductor light-emitting device technology, ultra-small chips with a size of several tens of micro millimeters and mounting technologies thereof are being developed to secure light source technology for ultra-thin surface lighting.

The present disclosure proposes an ultra-thin surface light source structure for application to household appliances.

### SUMMARY

An aspect of the present disclosure is to provide a surface light source structure with a minimized bezel portion and thickness.

Furthermore, another aspect of the present disclosure is to provide a surface light source structure capable of maximizing heat dissipation performance without increasing the thickness of a lamp.

A lamp according to the present disclosure may include a substrate, a plurality of semiconductor light-emitting devices arranged on the substrate, a light guide layer disposed on the substrate, and provided with an incident light surface on which light emitted from the semiconductor light-emitting device is incident and a light exit surface from which the incident light is emitted, a first reflective layer disposed between the substrate and the light guide layer, and disposed on one surface of the light guide layer facing the light exit surface to reflect light, and a second reflective layer disposed to overlap with the plurality of semiconductor light-emitting devices, and disposed on one surface different from the one surface of the light guide layer on which the first reflective layer is disposed, wherein the first reflective layer is disposed on the same surface as the incident light surface, and the second reflective layer is disposed obliquely to the incident light surface to allow light incident on the incident light surface to travel along the light guide layer.

According to an embodiment, the light guide layer may have a side surface portion formed obliquely to the incident light surface, and the second reflective layer may be disposed on the side surface portion.

According to an embodiment, an angle formed between the second reflective layer and the incident light surface may be greater than 0 degree and less than or equal to 45 degrees.

According to an embodiment, each of the semiconductor light-emitting devices may have a light-emitting surface from which light is emitted, and the semiconductor light-emitting device may be disposed to allow the light-emitting surface to face a thickness direction of the light guide layer.

According to an embodiment, the second reflective layer may be disposed to cover the entire light-emitting surface.

According to an embodiment, the lamp may further include a first heat dissipation layer disposed between the semiconductor light-emitting devices and the substrate, a via hole formed to pass through the substrate, a heat transfer portion formed in the via hole to be in contact with the first heat dissipation layer, and a second heat dissipation layer disposed below the substrate to be in contact with the heat transfer portion.

According to an embodiment, each of the semiconductor light-emitting devices may include a first electrode, a first semiconductor layer on which the first electrode is formed, an active layer formed on the first semiconductor layer, a second semiconductor layer formed on the active layer, and a second electrode spaced apart in a horizontal direction from the first electrode on the second semiconductor layer.

According to an embodiment, the heat transfer portion may be disposed to overlap with the first and second electrodes.

According to an embodiment, the heat transfer portion and the first and second heat dissipation layers may be made of the same material.

According to an embodiment, each of the heat transfer portion, and the first and second heat dissipation layers may be made of Cu.

According to an embodiment, the lamp may further include a phosphor layer disposed between the incident light surface and the semiconductor light-emitting device to absorb light of a specific wavelength and emit light different from the specific wavelength.

According to an embodiment, the phosphor layer may be formed in the form of a film, and attached to the incident light surface.

According to an embodiment, the semiconductor light-emitting device may emit blue light, and the phosphor layer may absorb the blue light to emit yellow light.

According to an embodiment, the lamp may further include a reflective pattern disposed between the light guide layer and the first reflective layer, and a distance between the reflective patterns may become narrower as they are further away from the semiconductor light-emitting devices.

According to an embodiment, the reflective pattern may have a lower refractive index than the light guide layer.

According to the present disclosure, a light source unit may be disposed at an lower side of a lamp, thereby allowing a lower side surface of a light guide layer to be used as an incident light surface. The lower side surface of the light guide layer may be made of a larger area than a light-emitting surface of the light source unit, thereby increasing the incident light efficiency of a light source without an additional structure.

Furthermore, according to the present disclosure, it is not necessary to increase a thickness of the light guide layer in order to increase the incident light efficiency of the light source unit, such as an edge-type lamp in the related art. Through this, the present disclosure may increase the incident light efficiency of the light source unit as well as reducing the thickness of the lamp.

In addition, according to the present disclosure, heat generated from the light source unit of the lamp may be rapidly diffused to an entire substrate and then discharged to the outside. Through this, the present disclosure may improve a heat dissipation efficiency of the lamp without increasing a thickness of a heat dissipation layer thereof.

### BRIEF DESCRIPTION OF THE DRAWINGS

FIG. 1 is a conceptual view showing a lamp disposed inside a refrigerator.

FIG. 2 is a cross-sectional view of a surface light source in the related art.

FIG. 3 is a perspective view of a lamp according to an embodiment of the present disclosure.

FIG. 4 is a cross-sectional view taken along line A-A in FIG. 3.

FIG. 5 is an exploded perspective view of a lamp according to the present disclosure.

FIG. 6 is an enlarged view of region B in FIG. 4.

FIG. 7 is a cross-sectional view of a lamp having a heat dissipation layer.

FIG. 8 is a perspective view showing a substrate of a lamp according to the present disclosure.

FIG. 9 is a cross-sectional view taken along line C-C in FIG. 8.

FIG. 10 is a conceptual view showing a heat dissipation layer provided in a lamp according to the present disclosure.

### DETAILED DESCRIPTION OF THE EMBODIMENTS

Hereinafter, the embodiments disclosed herein will be described in detail with reference to the accompanying drawings, and the same or similar elements are designated with the same numeral references regardless of the numerals in the drawings and their redundant description will be omitted. A suffix “module” and “unit” used for constituent elements disclosed in the following description is merely intended for easy description of the specification, and the suffix itself does not give any special meaning or function. In describing an embodiment disclosed herein, moreover, the detailed description will be omitted when specific description for publicly known technologies to which the invention pertains is judged to obscure the gist of the present disclosure. Also, it should be noted that the accompanying drawings are merely illustrated to easily explain the concept of the invention, and therefore, they should not be construed to limit the technological concept disclosed herein by the accompanying drawings.

Furthermore, it will be understood that when an element such as a layer, region or substrate is referred to as being “on” another element, it can be directly on the another element or an intermediate element may also be interposed therebetween.

A lamp described herein may include a portable phone, a smart phone, a laptop computer, a digital broadcast terminal, a personal digital assistant (PDA), a portable multimedia player (PMP), a navigation, a slate PC, a tablet PC, an ultrabook, a digital TV, a desktop computer, and the like. However, it would be easily understood by those skilled in the art that a configuration disclosed herein may be applicable to a lamp even though it is a new product type which will be developed later.

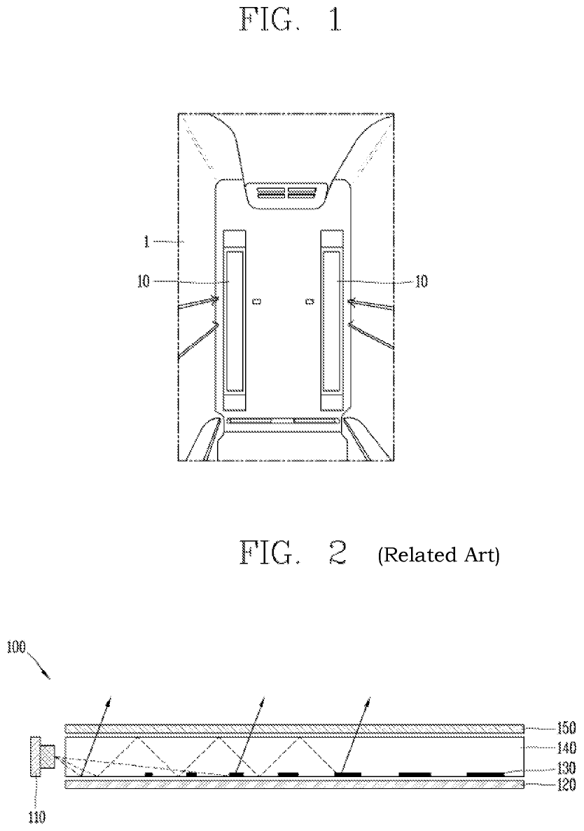

On the other hand, the lamp described herein may be used for various household appliances. For example, as shown in FIG. 1, a lamp 10 according to the present disclosure may be disposed inside a refrigerator 1. In order to maximize an amount of food storage, the volume of components disposed inside the refrigerator should be minimized. Since a thickness of the lamp according to the present disclosure is smaller than that of the lamp in the related art, it may be possible to efficiently secure an inner space of the refrigerator.

Prior to describing the lamp according to the present disclosure, the structure of a surface light source that has been applied to home appliances in the related art will be described.

FIG. 2 is a cross-sectional view of a surface light source in the related art.

As shown in FIG. 2, in the case of an edge-type surface light source in the related art, light emitted from a light source 110 enters an incident light surface of a light guide layer 140, and then is reflected from a reflective layer 120 and a reflective pattern 130 disposed below the light guide layer 140, and then emitted to a light exit surface of the light guide layer 140. Here, the incident light surface and the light exit surface are disposed perpendicular to each other. Light emitted from the light source is incident on a side of the light guide layer 140 and is emitted to a top surface thereof.

In order to construct a surface light source having a low thickness by the foregoing edge type, a thin light source and optical component are required. In particular, the light source needs a thickness that is smaller than that of the light guide layer 140 in order to increase the incident light efficiency. Specifically, the larger the incident light surface compared to the light-emitting surface provided in the light source, the higher the incident light efficiency of the light source. In the case of the edge-type lamp, since the incident light surface is formed on a side surface of the light guide layer, a thickness of the light guide layer must be increased in order to increase an area of the incident light surface.

However, since there is a limit in reducing a size of the light source, a thickness of the light guide layer 140 cannot be reduced to a predetermined level or more.

Meanwhile, according to the edge type, since the light source 110 is disposed on a side surface of the light guide layer 140, a bezel portion of the lamp is inevitably thick. Specifically, in order to increase an amount of light incident on the light guide layer 140, it is advantageous to secure a long light path from the light source 110 to the light guide layer 140. To this end, an optical gap layer may be disposed between the light source 110 and the light guide layer 140, which is a factor that increases a thickness of the bezel portion of the lamp.

On the other hand, in a light source using semiconductor light-emitting devices, there is a problem that the reliability, lifespan and efficiency of the lamp are reduced by heat generated from the semiconductor light-emitting devices. In a surface light source in the related art, heat dissipation characteristics are secured by directly attaching a heat radiator to the bezel portion and the substrate of the light source, but there is a problem that a thickness of the bezel portion of the light source increases or a thickness of the light source increases.

The present disclosure proposes a structure capable of minimizing a thickness of the lamp and a thickness of the bezel portion of the lamp as well as securing heat dissipation characteristics.

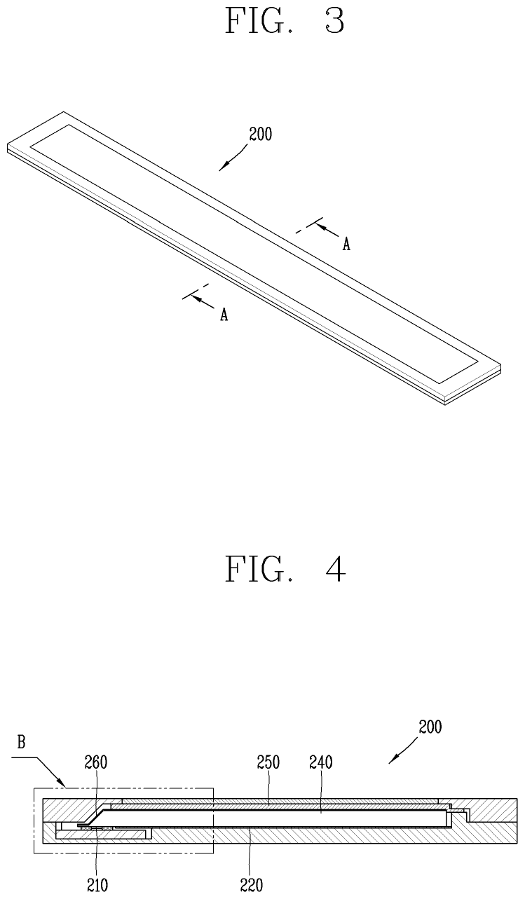

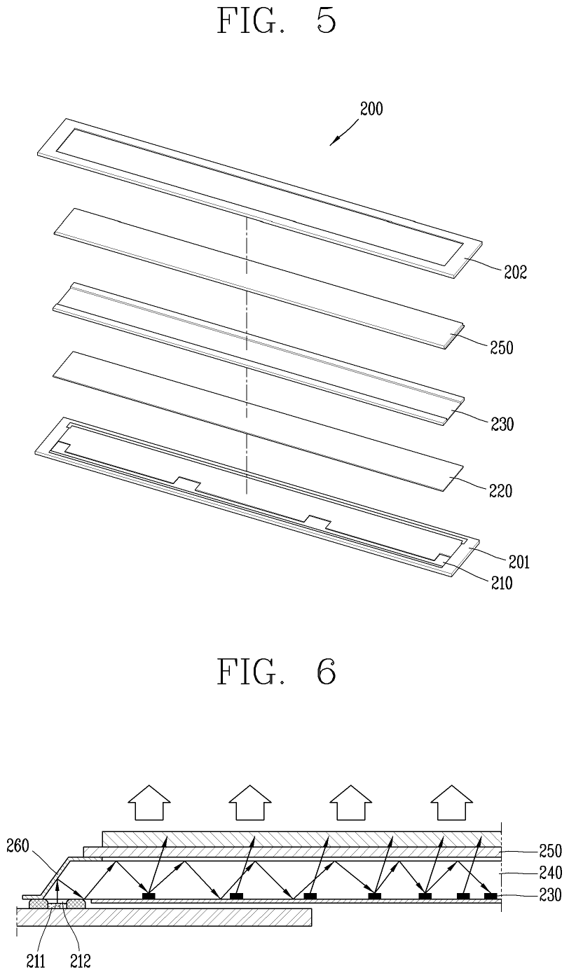

FIG. 3 is a perspective view of a lamp according to an embodiment of the present disclosure, and FIG. 4 is a cross-sectional view taken along line A-A in FIG. 3, and FIG. 5 is an exploded perspective view of a lamp according to the present disclosure, and FIG. 6 is an enlarged view of region B in FIG. 4.

The present disclosure includes a substrate 201, a light source unit 210, a light guide layer 240, a first reflective layer 220 and a second reflective layer 260. Hereinafter, the foregoing components will be described in detail with reference to the accompanying drawings.

Referring to a cross section of the lamp 200 according to the present disclosure, the light source unit 210 is disposed on the substrate 201. The light source unit 210 may include a plurality of semiconductor light-emitting devices. There may be two types of semiconductor light-emitting devices that are used in the present disclosure.

First, a flip chip type light-emitting device may be used for the light source unit 210.

For example, the semiconductor light-emitting device includes a p-type electrode, a p-type semiconductor layer on which the p-type electrode is formed, an active layer formed on the p-type semiconductor layer, an n-type semiconductor layer formed on the active layer, and an n-type electrode spaced apart in a horizontal direction from the p-type electrode on the n-type semiconductor layer. In the case of the foregoing flip chip type semiconductor light-emitting device, since an electrode for applying voltage to p-type and n-type electrodes is disposed below a light-emitting surface of the semiconductor light-emitting device, the electrode does not cover the light-emitting surface of the semiconductor light-emitting device. Therefore, the flip chip type semiconductor light-emitting device has an advantage of increasing the light quantity of the lamp.

For another example, the semiconductor light-emitting device may be a vertical semiconductor light-emitting device. Specifically, the vertical semiconductor light-emitting device includes a p-type semiconductor layer, an active layer formed on the p-type semiconductor layer, an n-type semiconductor layer formed on the active layer, and an n-type electrode formed on the n-type semiconductor layer. In this case, an electrode that supplies a voltage to the n-type electrode is disposed above a light-emitting surface of the semiconductor light-emitting device. Accordingly, part of the electrode covers the light-emitting surface, but the vertical semiconductor light-emitting device has a great advantage of reducing chip size because the electrode can be arranged in a top/down direction.

The semiconductor light-emitting device has a light-emitting surface to emit light in a direction toward the light-emitting surface. Light emitted to the light-emitting surface is emitted to the outside through the light guide layer 240.

The light guide layer 240 is made of a light transmitting material. For example, the light guide layer 240 may be made of PMMA, acryl, PC, glass, or the like.

The light guide layer 240 includes an incident light surface to which light emitted from the light source unit 210 is incident and a light exit surface from which light emitted from the light source unit 210 exits to the outside. A light-emitting surface of the semiconductor light-emitting device is disposed to face the incident light surface. In the foregoing edge-type lamp, the light-emitting surface of the semiconductor light-emitting device is disposed to face a side surface of the light guide layer, whereas in a lamp according to the present disclosure, the light-emitting surface is disposed to face a thickness direction of the light guide layer 240. Accordingly, the incident light surface and the light exit surface are arranged to face each other.

In order to increase the light uniformity of the lamp, light emitted from the light source unit must be uniformly emitted to the entire light exit surface. The first and second reflective layers allow light emitted from the light source unit to travel along the light guide layer, and then to be evenly emitted to the light exit is surface of the light guide layer.

The first reflective layer 220 is disposed to face the light exit surface, and reflects light traveling to a surface opposite to the light exit surface. The light guide layer 240 of the lamp according to the present disclosure is disposed such that the incident light surface and the light exit surface face each other. The first reflective layer 220 is disposed to face the incident light surface. Accordingly, the first reflective layer 220 and the light-emitting surface of the semiconductor light-emitting device face the same direction. For this reason, light emitted from the semiconductor light-emitting device does not immediately reach the first reflective layer 220.

The second reflective layer 260 allows light emitted from the semiconductor light-emitting device to travel along the light guide layer 240 or to reach the first reflective layer 220. To this end, the second reflective layer 260 overlaps with the light source unit 210, and is disposed obliquely to the incident light surface. Accordingly, the second reflective layer 260 overlaps with the semiconductor light-emitting devices, and is disposed obliquely to the light-emitting surface of the semiconductor light-emitting device.

Specifically, the light guide layer 240 has a side surface portion formed obliquely to the incident light surface, and the second reflective layer 260 is disposed on the side surface portion formed obliquely to the incident light surface.

In one embodiment, an angle formed by the second reflective layer 260 and the incident light surface may be 45 degrees or less. In addition, an area in which the second reflective layer 260 is projected to the light source unit 210 may be larger than that of the light source unit 210. In other words, the second reflective layer 260 is disposed to cover an entire light-emitting surface of the semiconductor light-emitting devices provided in the light source unit 210. Through this, it may be possible to increase the incident light efficiency of the light source unit 210.

According to the foregoing structure, as illustrated in FIG. 6, light emitted from the light source unit 210 is reflected by the second reflective layer 260, proceeds along the light guide layer 240, and then reflected by the first reflective layer 220 while traveling along the light guide layer 240 to be emitted to the light exit surface.

Meanwhile, as shown in FIG. 6, the light source unit 210 may include a semiconductor light-emitting device 211 and a phosphor layer 212. The phosphor layer 212 absorbs light of a predetermined wavelength emitted from the semiconductor light-emitting device 211 to emit light having a wavelength different from the predetermined wavelength. In one embodiment, the semiconductor light-emitting device emits blue light, and the phosphor layer 212 may absorb blue light to emit yellow light. In this case, yellow light emitted from the phosphor layer 212 and some blue light not absorbed by the phosphor layer 212 are combined to implement white light. Accordingly, white light is emitted to the outside.

Meanwhile, the phosphor layer 212 may be formed in the form of a film, and may be attached to the incident light surface. The phosphor layer 212 may be attached to the incident light surface, and the semiconductor light-emitting device 211 may be disposed to overlap with the phosphor layer 212 to convert light emitted from the semiconductor light-emitting device 211 to photo-convert light emitted from the semiconductor light-emitting device 211. According to this structure, a support element for supporting the phosphor layer 212 and a bonding element for bonding the phosphor layer 212 to the semiconductor light-emitting device 211 may not be required, thereby simplifying the structure of the lamp.

Meanwhile, a reflective pattern 230 may be disposed between the light guide layer 240 and the first reflective layer 220. A distance between the reflective patterns 230 becomes narrower as they are further away from the light source unit 210. The reflective pattern 230 induces total reflection around the light source unit 210 and induces scattering from a side away from the light source unit 210. Through this, the reflective pattern 230 prevents a region closer to the light source unit 210 from being brighter than other regions, and prevents a region further away from the light source unit 210 from being darker than other regions.

A material constituting the reflective pattern 230 that allows light to be totally reflected from the reflective pattern 230 may have a lower refractive index than that constituting the light guide layer 240.

Meanwhile, the light diffusion layer 250 may be disposed on the light exit surface provided in the light guide layer 240. The light diffusion layer 250 is made of a light transmitting material, and serves to increase an optical path of light emitted to the outside so as to enhance the light uniformity of the lamp.

According to the foregoing structure, a light source unit may be disposed at an lower side of a lamp, thereby allowing a lower side surface of a light guide layer to be used as an incident light surface. The lower side surface of the light guide layer may be made of a larger area than a light-emitting surface of the light source unit, thereby increasing the incident light efficiency of a light source without an additional structure. Furthermore, according to the foregoing structure, it may not be required to increase a thickness of the light guide layer in order to increase the incident light efficiency of the light source unit, such as an edge-type lamp in the related art. Through this, the present disclosure may increase the incident light efficiency of the light source unit as well as reducing the thickness of the lamp.

Meanwhile, since the semiconductor light-emitting device included in the light source unit 210 is sensitive to heat, heat dissipation performance is very important in order to increase the lifespan and reliability of the lamp. The present disclosure proposes a structure capable of maximizing heat dissipation performance as well as minimizing a thickness of the lamp according to the present disclosure.

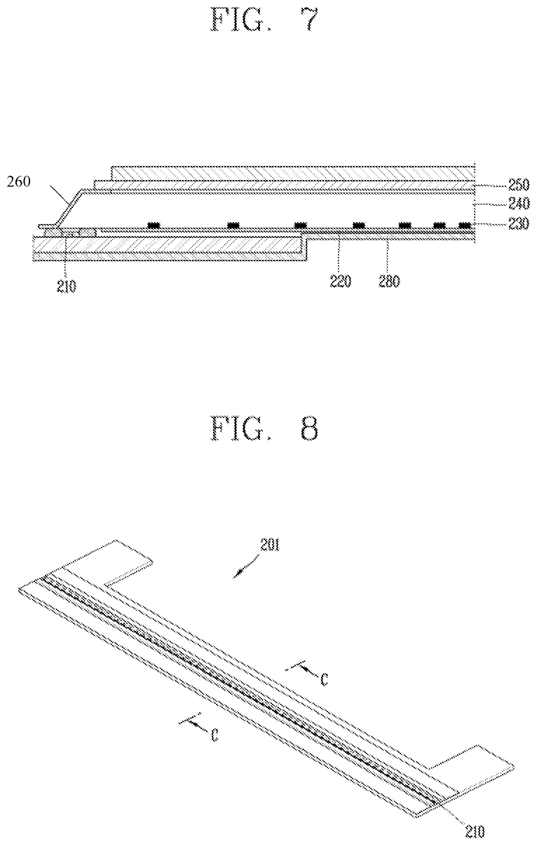

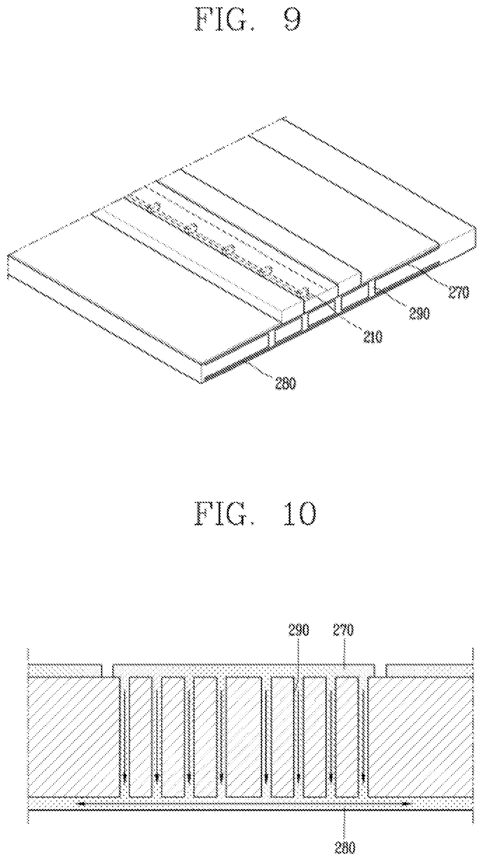

FIG. 7 is a cross-sectional view of a lamp having a heat dissipation layer, and FIG. 8 is a perspective view showing a substrate of a lamp according to the present disclosure, and FIG. 9 is a cross-sectional view taken along line C-C in FIG. 8, and FIG. 10 is a conceptual view showing a heat dissipation layer provided in a lamp according to the present disclosure.

Referring to FIG. 7, a heat dissipation layer may be disposed below the lamp according to the present disclosure. Specifically, the lamp according to the present disclosure may be provided with first and second heat dissipation layers, but only the second heat dissipation layer 280 is illustrated in FIG. 7. The second heat dissipation layer 280 discharges heat generated from the light source unit 210 to a lower side of the lamp.

However, it is difficult to effectively discharge heat generated from the light source unit 210 with only the second heat dissipation layer 280. Hereinafter, a structure for effectively discharging heat generated from the light source unit 210 will be described.

The light source unit 210 is disposed on the substrate 201 according to the present disclosure. The heat generated from the light source unit 210 is discharged to the outside through a heat dissipation layer, and the heat dissipation layer is disposed below the light source unit 210. Specifically, referring to FIG. 9, a first heat dissipation layer 270 and a second heat dissipation layer 280 are disposed below the light source unit 210. The first heat dissipation layer 270 is disposed directly under the light source unit 210 to directly receive heat generated from the light source unit 210, and the second heat dissipation layer 280 is disposed below the substrate 201. The substrate 201 is disposed with the first heat radiation layer 270 and the second heat radiation layer 280 therebetween.

The second heat dissipation layer 280 receives heat from the first heat dissipation layer 270 to discharges heat to the outside. A via hole may be formed in the substrate 201 to quickly transfer heat from the first heat dissipation layer 270 to the second heat dissipation layer 280. A heat transfer portion 290 in contact with each of the first heat dissipation layer 270 and the second heat dissipation layer 280 may be disposed inside the via hole. The heat transfer portion 290 and the first and second heat dissipation layers 270, 280 may be made of the same material. For example, the first and second heat dissipation layers 270, 280 may be made of Cu having a high thermal conductivity.

The heat transferred to the heat transfer portion 290 is quickly transferred to the second heat dissipation layer 280 and the substrate 201. Through this, heat generated from the light source unit 210 may be quickly dispersed to the surroundings.

Meanwhile, the heat transfer unit 290 may be formed in a region with a large amount of heat being generated in the entire region of the light source unit 210. Specifically, when the semiconductor light-emitting device used in the light source unit 210 is a flip chip type semiconductor light-emitting device, the semiconductor light-emitting device may include a first electrode, a first semiconductor layer on which the first electrode is formed, an active layer formed on the first semiconductor layer, a second semiconductor layer formed on the active layer, and a second electrode spaced apart in a horizontal direction from the first electrode on the second semiconductor layer. In this case, the amount of heat generated from the first and second electrodes is the largest. The heat transfer portion 290 may be disposed to overlap with the first and second electrodes to quickly discharge heat generated from the semiconductor light-emitting device to the outside.

Meanwhile, when the semiconductor light-emitting device used in the light source unit 210 is a vertical semiconductor light-emitting device, the semiconductor light-emitting device includes a first semiconductor layer, an active layer formed on the first semiconductor layer, a second semiconductor layer formed on the active layer, and a second electrode formed on the second semiconductor layer. In this case, the heat transfer portion 290 may be formed to overlap with the first electrode.

In addition, according to the present disclosure, heat generated from the light source unit of the lamp may be rapidly diffused to an entire substrate and then discharged to the outside. Through this, the present disclosure may improve a heat dissipation efficiency of the lamp without increasing a thickness of a heat dissipation layer thereof.

The configurations and methods according to the above-described embodiments will not be applicable in a limited way to a lamp using the foregoing semiconductor light-emitting device, and all or part of each embodiment may be selectively combined and configured to make various modifications thereto.

1. A lamp, comprising:
a substrate;
a plurality of semiconductor light-emitting devices arranged on the substrate;
a light guide layer disposed on the substrate, and provided with an incident light surface on which light emitted from the plurality of semiconductor light-emitting devices is incident and a light exit surface from which the light is emitted;
a first reflective layer disposed between the substrate and the light guide layer, and disposed on one surface of the light guide layer facing towards the light exit surface to reflect the light; and
a second reflective layer disposed to overlap with the plurality of semiconductor light-emitting devices, and disposed on another surface different from the one surface of the light guide layer on which the first reflective layer is disposed,
wherein the first reflective layer is disposed on the same surface as the incident light surface, and
wherein the second reflective layer is disposed obliquely to the incident light surface to allow light incident on the incident light surface to travel along the light guide layer.

2. The lamp of claim 1, wherein the light guide layer has a side surface portion formed obliquely to the incident light surface, and
wherein the second reflective layer is disposed on the side surface portion.

3. The lamp of claim 1, wherein an angle formed between the second reflective layer and the incident light surface is greater than 0 degree and less than or equal to 45 degrees.

4. The lamp of claim 1, wherein each of the semiconductor light-emitting devices has a light-emitting surface from which light is emitted, and
wherein the plurality of semiconductor light-emitting devices disposed to allow the light-emitting surface to face a thickness direction of the light guide layer.

5. The lamp of claim 4, wherein the second reflective layer is disposed to cover the entire light-emitting surface.

6. The lamp of claim 1, further comprising:
a first heat dissipation layer disposed between the plurality of semiconductor light-emitting devices and the substrate;
a via hole formed to pass through the substrate;
a heat transfer portion formed in the via hole to be in contact with the first heat dissipation layer; and
a second heat dissipation layer disposed below the substrate to be in contact with the heat transfer portion.

7. The lamp of claim 6, wherein each of the plurality of semiconductor light-emitting devices comprises:
a first electrode;
a first semiconductor layer on which the first electrode is formed;
an active layer formed on the first semiconductor layer;
a second semiconductor layer formed on the active layer; and
a second electrode spaced apart in a horizontal direction from the first electrode on the second semiconductor layer.

8. The lamp of claim 7, wherein the heat transfer portion is disposed to overlap with the first and second electrodes.

9. The lamp of claim 6, wherein the heat transfer portion and the first and second heat dissipation layers are made of the same material.

10. The lamp of claim 6, wherein each of the heat transfer portion, and the first and second heat dissipation layers is made of Cu.

11. The lamp of claim 1, further comprising:
a phosphor layer disposed between the incident light surface and the plurality of semiconductor light-emitting devices to absorb light of a specific wavelength and emit light different from the specific wavelength.

12. The lamp of claim 11, wherein the phosphor layer is formed in the form of a film, and is attached to the incident light surface.

13. The lamp of claim 11, wherein the plurality of semiconductor light-emitting devices emit blue light, and
wherein the phosphor layer absorbs the blue light to emit yellow light.

14. The lamp of claim 1, further comprising:
a reflective patterns disposed between the light guide layer and the first reflective layer, and
a distance between the reflective patterns becomes narrower as the reflective patterns are further away from the plurality of semiconductor light-emitting devices.

15. The lamp of claim 14, wherein the reflective pattern has patterns have a lower refractive index than that of the light guide layer.

16. The lamp of claim 1, wherein lamp has an elongated shape having long edges and short edges, and
wherein the second reflective layer is located at one of the long edges.

17. The lamp of claim 1, wherein the plurality of light-emitting devises are arranged along the one of the long edges.

18. The lamp of claim 1, wherein an incident direction of the light emitted from the plurality of semiconductor light-emitting devices is substantially parallel to an exit direction of the light that is emitted from the light exit surface.

19. A lighting device, comprising:
a substrate;
a plurality of semiconductor light-emitting devices arranged on the substrate;
a light guide layer disposed on the substrate, and provided with an incident light surface on which light emitted from the plurality of semiconductor light-emitting devices is incident and a light exit surface from which the light is emitted, the incident light surface being closer to the plurality of semiconductor light-emitting devices than the light exit surface; and
a reflective layer disposed over the plurality of semiconductor light-emitting devices and arranged obliquely to the incident light surface to allow the light incident on the incident light surface to travel along the light guide layer.

20. The lighting device of claim 19, wherein lighting device has an elongated shape having long edges and short edges, and
wherein the reflective layer is located at one of the long edges.
